(19) United States
(12) Patent Application Publication
(10) Pub. No.: US 2011/0163428 A1
(43) Pub. Date: Jul. 7, 2011

(54) SEMICONDUCTOR PACKAGES WITH EMBEDDED HEAT SINK

(76) Inventors: Manolito Fabres Galera, Singapore (SG); Leocadio Morona Alabin, Singapore (SG); In Suk Kim, Sommerville Park (SG)

(21) Appl. No.: 12/652,491

(22) Filed: Jan. 5, 2010

(51) Int. Cl. H01L 23/495

(52) U.S. Cl. 257/675; 257/E23.051

(57) ABSTRACT

Semiconductor packages and methods for making and using the same are described. The semiconductor packages contain a leadframe having an array of holes with a layout corresponding to the land pad array of the package, wherein the holes contain a thermally-conductive dielectric material with a via therein containing an electrically conductive material. The electrically conductive materials can extend past the bottom of the leadframe to form the land pad array of the packages. With such a configuration, the leadframe can act as an embedded heat sink in the package and there is no need to mount an additional heat sink to the package for thermal dissipation, allowing a thinner package to be manufactured. With such a configuration, the semiconductor packages have a full land pad array, providing a smaller footprint and a higher I/O capacity. Other embodiments are also described.

### FIELD

This application relates generally to semiconductor devices and methods for making such devices. More specifically, this application describes semiconductor packages that contain a modified lead frame that acts as an embedded heat sink, as well as methods for making and using such packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to semiconductor packages and methods for making and using the same. The semiconductor packages contain a leadframe having an array of holes with a layout corresponding to the land pad array of the package, wherein the holes contain a thermally-conductive dielectric material with a via therein containing an electrically conductive material. The electrically conductive materials can extend past the bottom of the leadframe to form the land pad array of the packages. With such a configuration, the leadframe can act as an embedded heat sink in the package and there is no need to mount an additional heat sink to the package for thermal dissipation, allowing a thinner package to be manufactured. With such a configuration, the semiconductor packages have a full land pad array, providing a smaller footprint and a higher I/O capacity.

### BRIEF DESCRIPTION OF THE DRAWINGS

The following description can be better understood in light of the Figures, in which:

FIG. 1 shows some embodiments of a method for making semiconductor packages containing a lead frame with an array of holes;

FIG. 2 depicts some embodiments of a method for making semiconductor packages where the array of holes have been filled with thermally-conductive dielectric material;

FIGS. 3 and 4 depict some embodiments of a method for making semiconductor packages containing via holes in the thermally-conductive dielectric material;

FIG. 5 depicts some embodiments of a method for making semiconductor packages with the via holes filled with an electrically-conductive material;

FIG. 6 depicts some embodiments of a method for making semiconductor packages with a solder mask formed over the upper surface of the leadframe;

FIG. 7 depicts some embodiments of a method for making semiconductor packages with openings in the solder mask;

FIG. 8 shows some embodiments of a method for making semiconductor packages with routing connectors formed in the openings of the solder mask;

FIGS. 9 shows some embodiments of a method for making semiconductor packages showing a die with an IC device;

FIG. 10 depicts some embodiments of a method for making semiconductor packages where the die has been attached to the leadframe;

FIGS. 11 and 12 depict top and bottom views of methods for making semiconductor packages with a molding material;

FIGS. 13 and 14 show some embodiments of a method for making semiconductor packages containing a land pad array and heat sink terminals;

FIGS. 15 and 16 show other embodiments of a method for making semiconductor packages containing a solder mask underlying the land pad array and heat sink terminals;

FIG. 17 shows a side view of a some embodiments of a completed semiconductor package; and

FIG. 18 depicts some embodiments of the locking feature contained in the leadframe of a semiconductor package.

The Figures illustrate specific aspects of the semiconductor packages that contain an embedded heat sink and methods for making and using such packages. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and associated methods of using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor devices in the IC industry, it could be used for and applied to other electronic devices like optoelectronic devices, solar cells, MEMS structures, lighting controls, power supplies, and amplifiers.

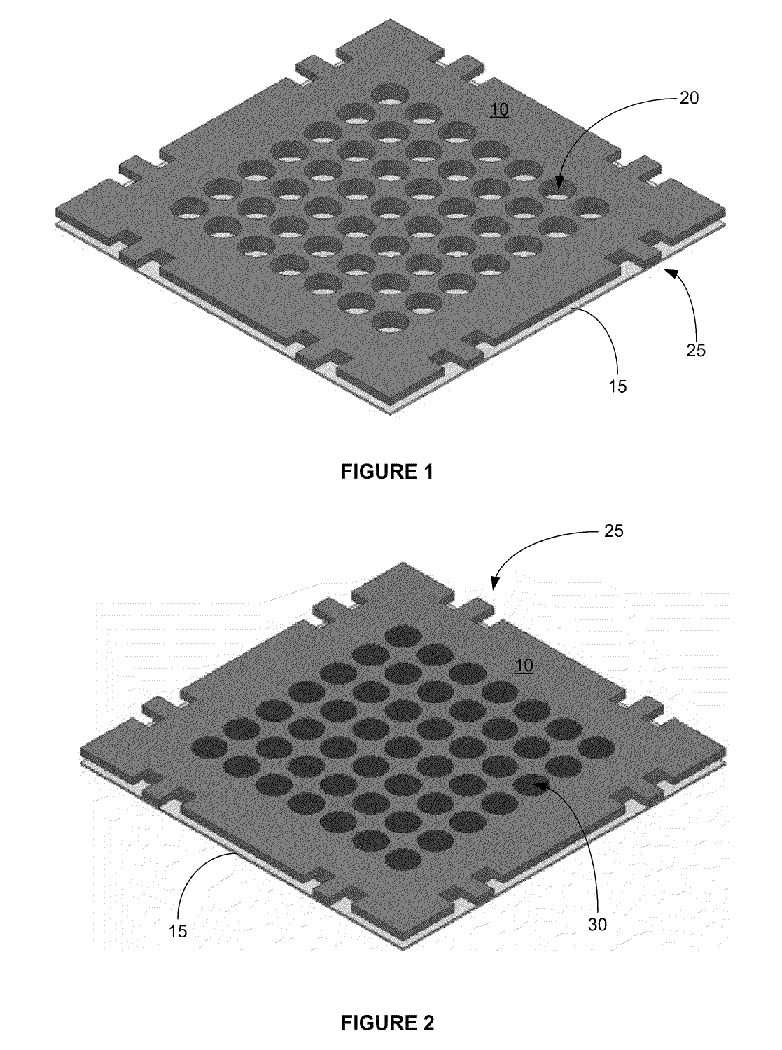

Some embodiments of the semiconductor packages and methods for making such packages are shown in the FIGS. 1-18. In these embodiments, the methods for making the semiconductor packages begin by providing a lead frame (or leadframe) 10 on a tape 15. The tape 15 can be any substrate known in the art that can provide support to the leadframe 10 during the manufacturing process, yet can be removed from the leadframe 10 when needed. In some embodiments, the tape 15 comprises a thermoplastic resin with adhesives or a thermosetting film.

The lead frame 10 can be any lead frame known in the semiconductor art. In some embodiments, the lead frame 10 can be manufactured using any known process, such as by using a stamping or an etching process. In other embodiments, the lead frame 10 can be manufactured by a stamping process since it simpler, easier, and cheaper than using an etching process.

The lead frame 10 can have any size and thickness that is needed for the completed semiconductor package. Thus, the size and thickness of the lead frame 10 will depend on the integrated circuit (IC) die (or dies) that will be contained in final semiconductor package. The lead frame 10 can comprise any conductive metal or metal alloy known in the art, including Cu, Ni—Pd, Ni—Pd—Au, Ni—Pd—Au/Ag, or combinations thereof. In some embodiments, the lead frame comprises Cu or a Cu alloy.

The lead frame 10 can have a substantially rectangular configuration, as shown in the embodiments depicted in FIG. 1. The lead frame 10 can then be modified so that it is provided with leadframe holes (or holes) 20, as shown in FIG. 1. The leadframe holes 20 can be provided by any process known in the art, including a stamping or etching process. In some embodiments, leadframe the holes 20 can be provided by any etching process. The leadframe holes can be provided in those locations in the leadframe 10 where the land pads (or terminals) of the package need to be located.

In some embodiments, the leadframe 10 can also be provided with a locking feature(s) 25, as shown in FIG. 1. In some embodiments, the locking feature(s) 25 can be provided at the same time, before, or after providing the leadframe holes 20. In some embodiments, the locking feature(s) 25 can be provided at substantially the same time at the holes 20 and using a similar process. The locking feature(s) 25 can be used to improve the encapsulant adhesion to the leadframe and so are provided in the leadframe 10 in any location that will support such an operation, including in the locations depicted in FIG. 1. In other embodiments, rather than a dual process of providing the leadframe 10 and then forming leadframe holes 20 and locking feature 25, the leadframe 10 can be provided with the configuration shown in FIG. 1 in a single process.

Next, as shown in FIG. 2, the leadframe holes 20 can be filled with a thermally-conductive dielectric material to form an insulating layer (or isolation via) 30 within each hole. Examples of thermally-conductive dielectric or insulating materials that can be used to form the insulating layer 30 include polymer-filled epoxy materials or ceramic-filled epoxy materials. The leadframe holes 20 can be filled using any process known in the art, including any dispensing or screen printing process. In some embodiments, the leadframe holes 20 can be filled with the thermally-conductive dielectric material by screen printing and/or stencil printing.

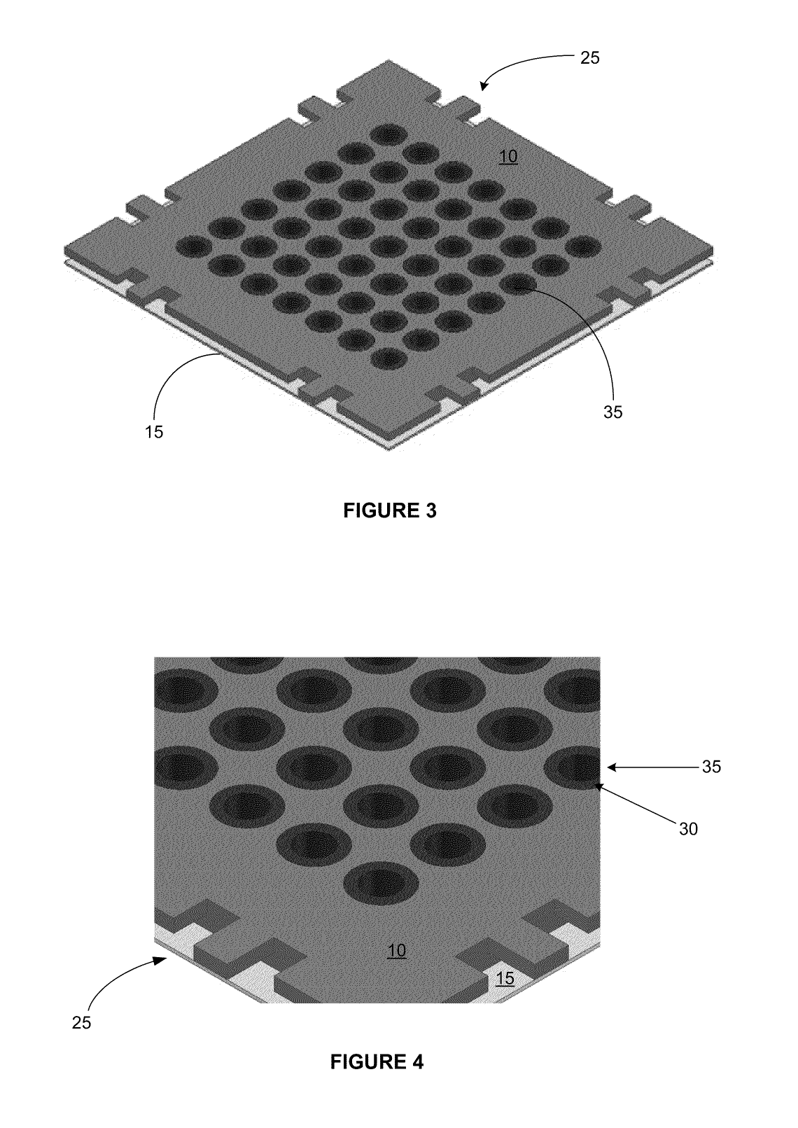

Next, as shown in FIG. 3 (with a close-up view shown in FIG. 4), a second (or via) hole 35 is then created in the insulating layer 30. Any process that removes the thermally-conductive dielectric material from an inner portion of the insulating layer 30 can be used to form the via hole 35. In some embodiments, the via hole 35 is created by a buffing process that uses a buffing wheel followed by a laser drilling process that uses a water-guided laser or a mechanical drilling process. As shown in FIG. 4, the result of this process is the formation of via holes 35 in an inner portion of leadframe holes 20 with the thermally-conductive dielectric material remaining in an outer portion of the leadframe holes 20. While holes 20 and via holes 35 are depicted as circular in shape, they can be configured with other shapes such as oblong or rectangular.

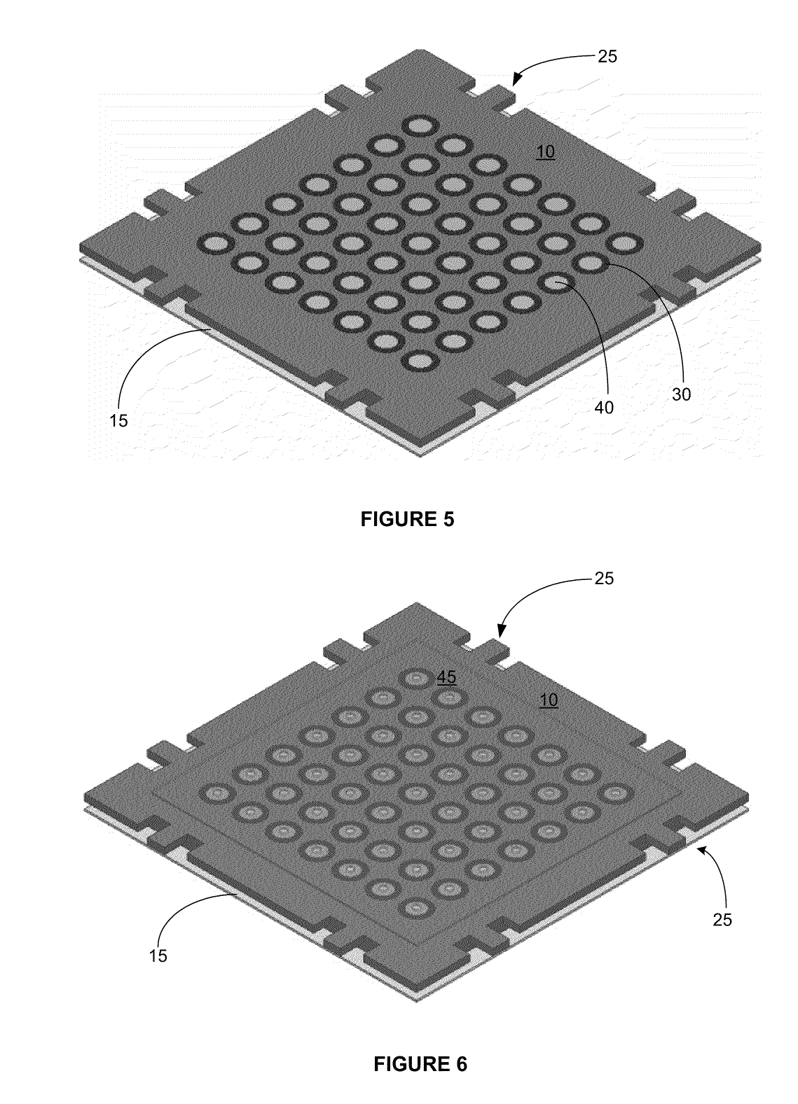

As shown in FIG. 5, the via holes 35 can then be filled in with an electrically-conductive material to form conductive layer 40. The conductive layer 40 can be made using any via fill process known in the art, including dispensing or screen printing. The conductive layer 40 can comprise any conductive material known in the art, including Cu, Au, or Cu—Ag.

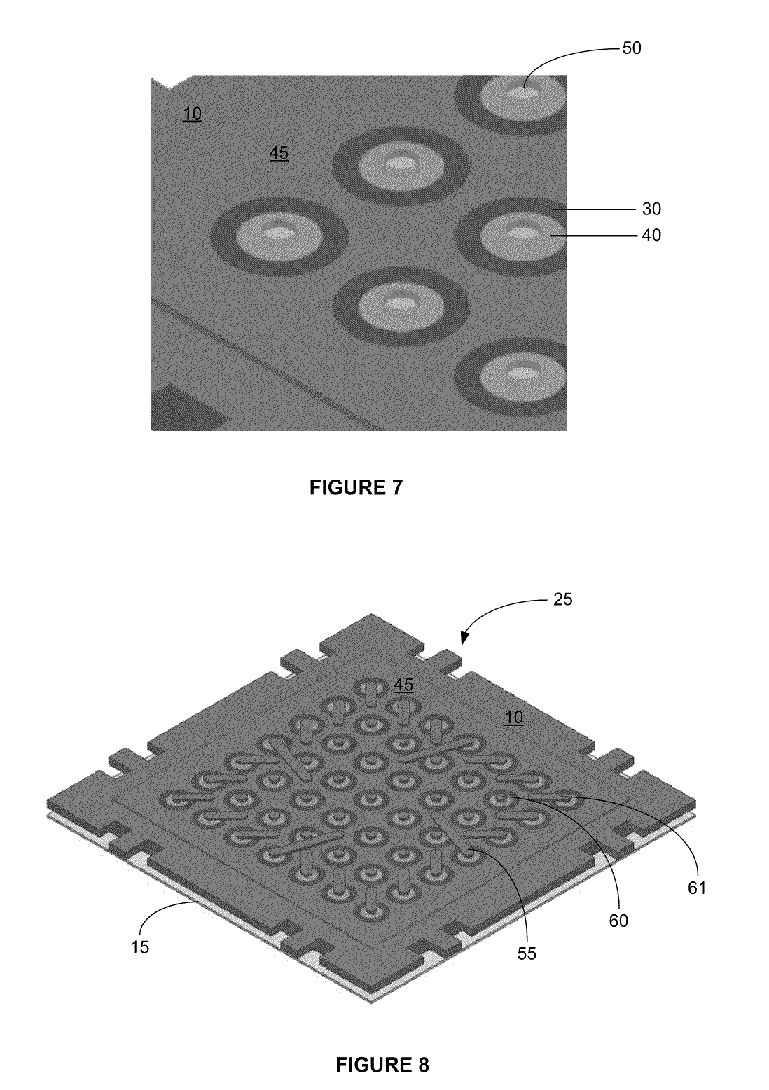

Then, as shown in FIG. 6, a solder mask 45 can be provided over the upper surface of the leadframe 10. The solder mask 45 can be provided using any process known in the art, including printing or photo-imaging processes. The solder mask 45 can comprise any suitable material known in the art, including wet films or dry films. In some embodiments, the solder mask 45 contains openings 50 in the mask that will be used in forming routing connectors 55, as described herein. So in these embodiments, the openings 50 can be substantially aligned over via holes 35 when the solder mask 45 is provided on the leadframe 10, as shown in FIG. 7. The openings 50 in the solder mask can be formed before or after the solder mask 45 is provided on the leadframe 10.

Next, as shown in FIG. 8, routing connectors 55 can be formed by using the solder mask 45. The routing connectors 55 can be formed using any process known in the art, including a plating process using electroplating, non-electroplating, or a printing process using screen printing or stencil printing. The routing connectors contain both vertical connectors 60 that extend up and away from the conductive layer 40 and horizontal connectors 61 that operate to distribute the layout for any desired pattern, i.e., for the connection to the IC device on the die (as described herein).

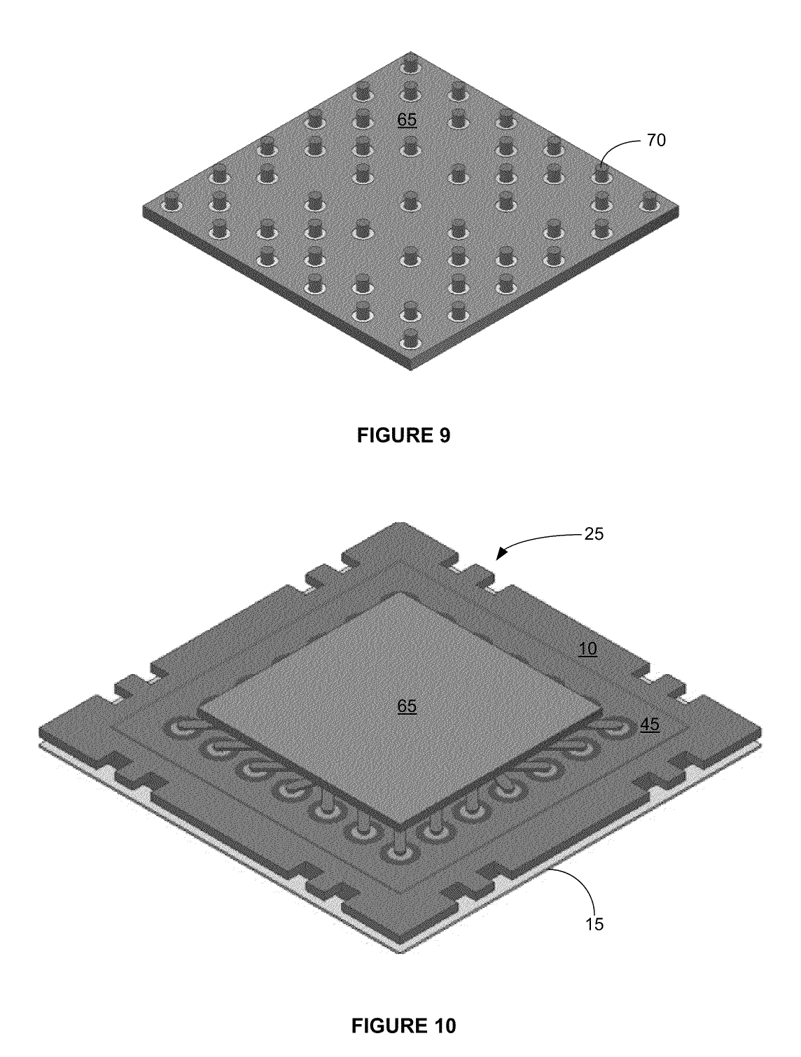

The process for making the semiconductor packages continues when a die 65 containing an IC device is provided, as illustrated in FIG. 9. The die 65 may be made of any suitable semiconductor material. Some non-limiting examples of such materials may include silicon, polysilicon, gallium arsenide, silicon carbide, gallium nitride, silicon and germanium, and the like.

The die 65 can contain any number or combination of IC devices. The IC device may be any integrated circuit (including any discrete device) known in the art. Some non-limiting examples of these devices may include logic or digital IC, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), and insulated-gate field-effect transistors (“IGFET”).

The die 65 is then attached to the routing connectors 55 on the leadframe 10. Any known flipchip process can be used to attach the die 65 to the leadframe 10. In some embodiments, the IC device(s) on the die 65 can be provided with a bond pad (not shown) as known in the art. The bond pads can be formed in the desired location by any process known in the art (such as a redistribution method) and can be made of any known solderable material, including Au, Cu, Ag, Ti, Ni, Sn, W, Ni, or combinations thereof.

An array of solder bumps (or pillars) 70 can then be provided on the bond pads as shown in FIG. 9. The bumps can be made of conductive material such as Ag, Sn, Pb, Cu, Sb, Au or combinations thereof. The bumps 70 can be provided on the bond pads through any process known in the art, including electroless plating, ball drop, or printing. Then, as shown in FIG. 10, the die 65 is flipped and placed on the lead frame 10 so the IC device(s) on the front side of the die 65 (through the pads/bumps) is attached to the desired location of routing connectors 55. The result of this process leaves the back side of the die 65 facing upwards. Optionally, an underfill process can be performed to provide a molding material between the die 65 and the leadframe 10.

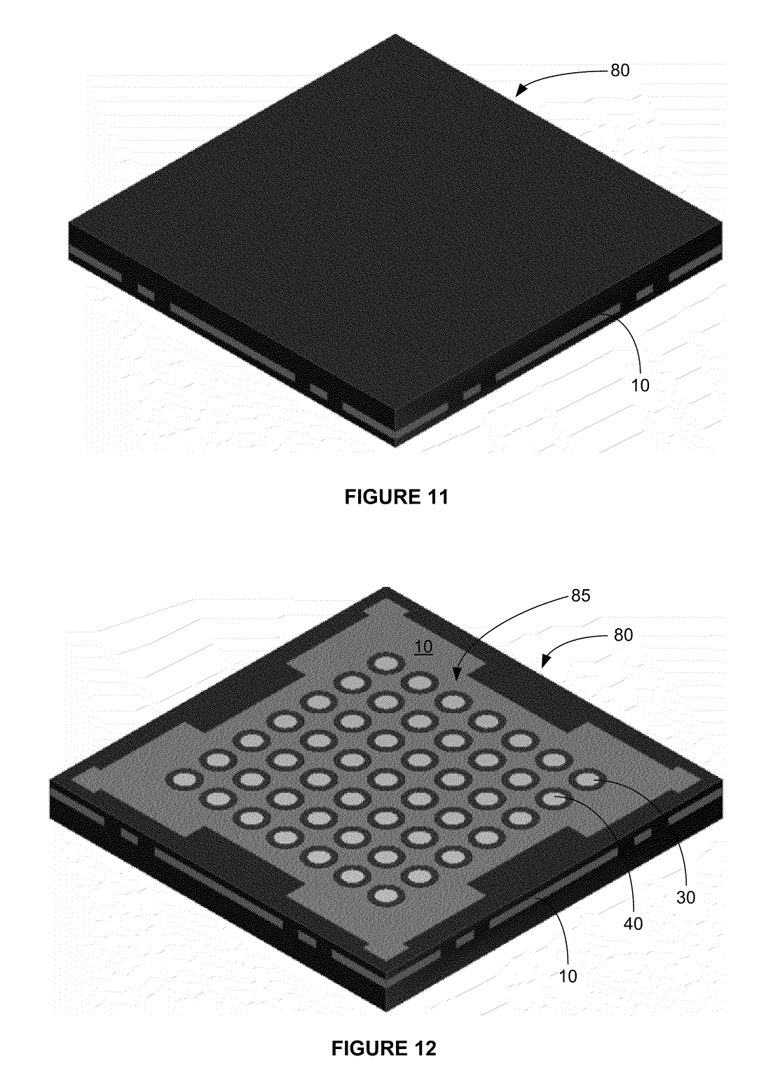

The lead frame 10 and the die 65 can then be encapsulated in any molding material 80 known in the art, as shown in FIG. 11 (top view) and FIG. 12 (bottom view). In some embodiments, the molding material 80 can comprise an epoxy molding compound, a thermoset resin, a thermoplastic material, or potting material. In other embodiments, the molding material comprises an epoxy molding compound. The molding material 80 may be formed using any encapsulation process known in the art, such as transfer or compression molding.

In some embodiments, the molding material 80 completely encapsulates the lead frame 10. In the illustrated embodiments, though, the molding material 80 does not completely encapsulate the bottom surface of the lead frame 10. Instead, the bottom of the leadframe 10, the thermally-conductive dielectric material of insulating layer 30, the via holes 35, and the conductive layer 40 remain exposed, as shown in FIG. 12.

The conductive layer 40 in the via holes 35 can serve as land pads (or lands) 85 in an LGA-type semiconductor package. The lands 85 can have any desired array on the lower or bottom surface of the semiconductor package and can be configured to be terminals for the external electronic device to which the semiconductor package will be attached (such as a printed circuit board). The lands 85 can have any configuration known in the art consistent with their operation as terminals for the semiconductor package. Thus, in the illustrated embodiments, the lands 85 are given a substantially circular configuration with a size ranging from about 0.20 mm to about 0.50 mm in diameter. In other embodiments, though, the lands 85 can have a rectangular or other suitable geometrical shape.

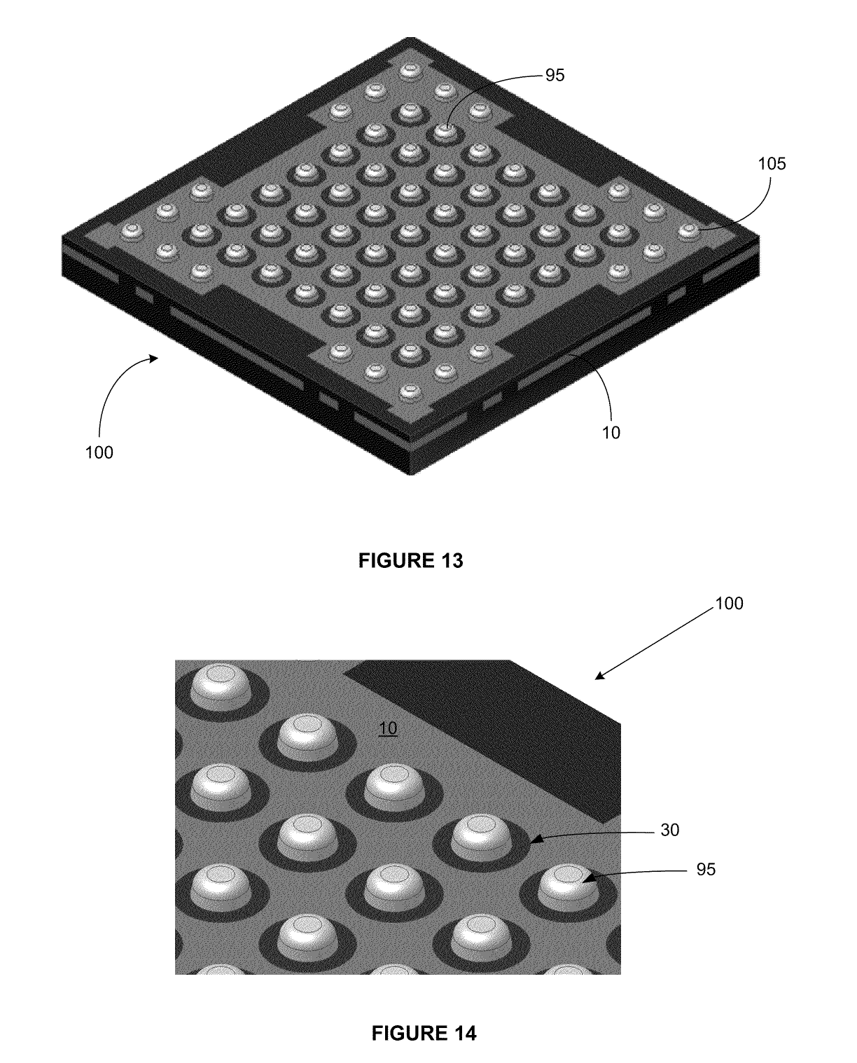

Optionally, the lands 85 can be plated and/or can be provided with a solder bump to provide a BGA-type semiconductor package. The lands 85 can be provided with solder bumps using any bumping process known in the art. For example, the bumping process can provide solder bumps 95 on the lands 85, as shown in FIG. 13 (with a close-up view shown in FIG. 14). The plating process can plate the lands 85 with any desired conductive material (such as Sn, SnPb, Au, Cu, or combinations thereof with any desired thickness) until a plate is formed.

The bottom surface of the semiconductor package 100 can also be provided with heat sink terminals. In these embodiments, the plating and/ solder bumps can be provided on the bottom surface of the lead frame 10 itself, rather than the lands 85, in any desired pattern that can maximize the amount of heat that is conducted through the bottom of the package 100. In the illustrated embodiments, the bottom surface of the leadframe 10 can be provided with plating and/or solder bumps 105 that do not cover any via hole 35. The plating and/or solder bumps 105 can be formed in a similar manner as the plating and/or solder bumps that are formed over the via holes 35.

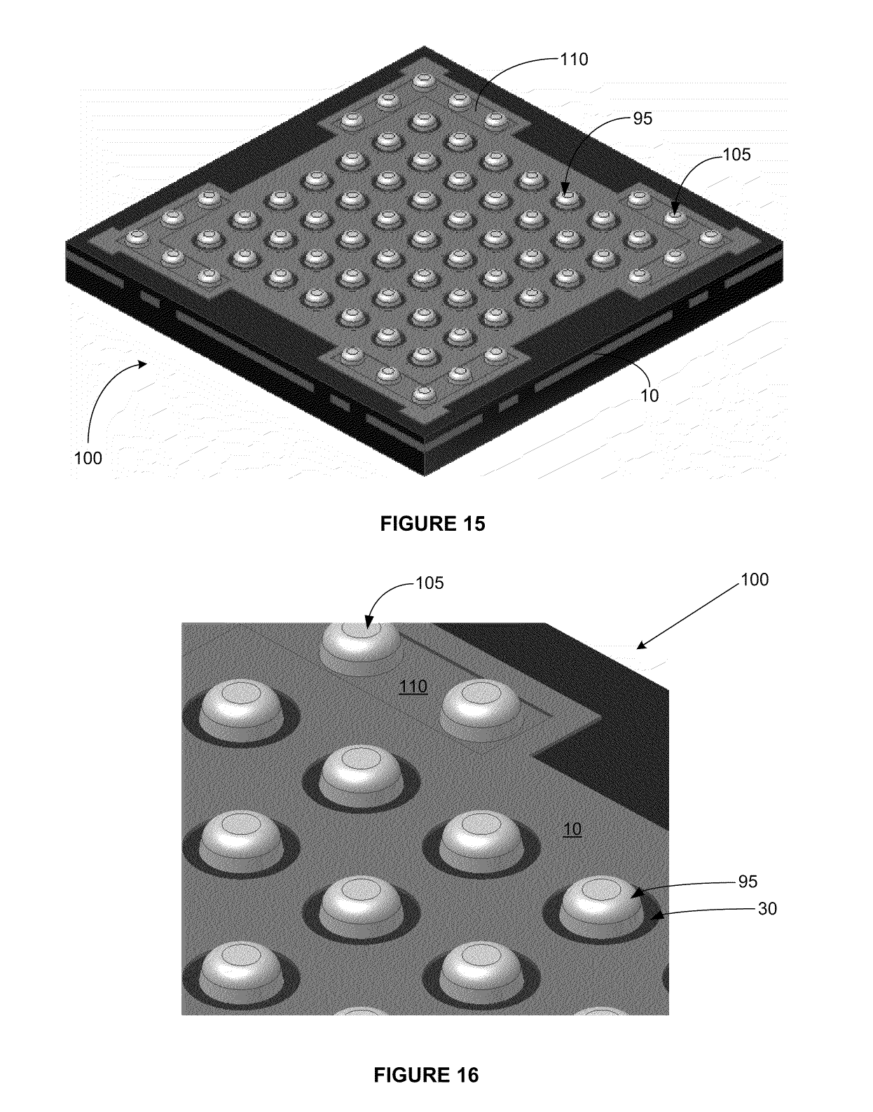

In some embodiments, an optional solder mask 110 can be used during the manufacturing process on the bottom side of the leadframe 10. Where the solder mask 110 has been used, the bottom of the leadframe 10 is depicted in FIG. 15. In these embodiments, the plating/solder bumps 95 are formed on the land pads 85 as described above. The plating/solder bumps 105 that operate as heat sink terminals can then be formed on the solder mask 110, which remains exposed as illustrated in FIG. 16.

The molded semiconductor package 100 can then be singulated. The singulation of the molded semiconductor package can be carried out using any process known in the art, including a saw singulation process. Then, the singulated semiconductor packages may be electrically tested, taped, and reeled using any processes known in the art to form a completed semiconductor package. The semiconductor packages can then be stacked and/or can then be connected to a printed circuit board (PCB) using the lands (that are optionally plated/bumped) and used in any electronic device known in the art such as portable computers, disk drives, USB controllers, portable audio devices, or any other portable/ultraportable electronic devices.

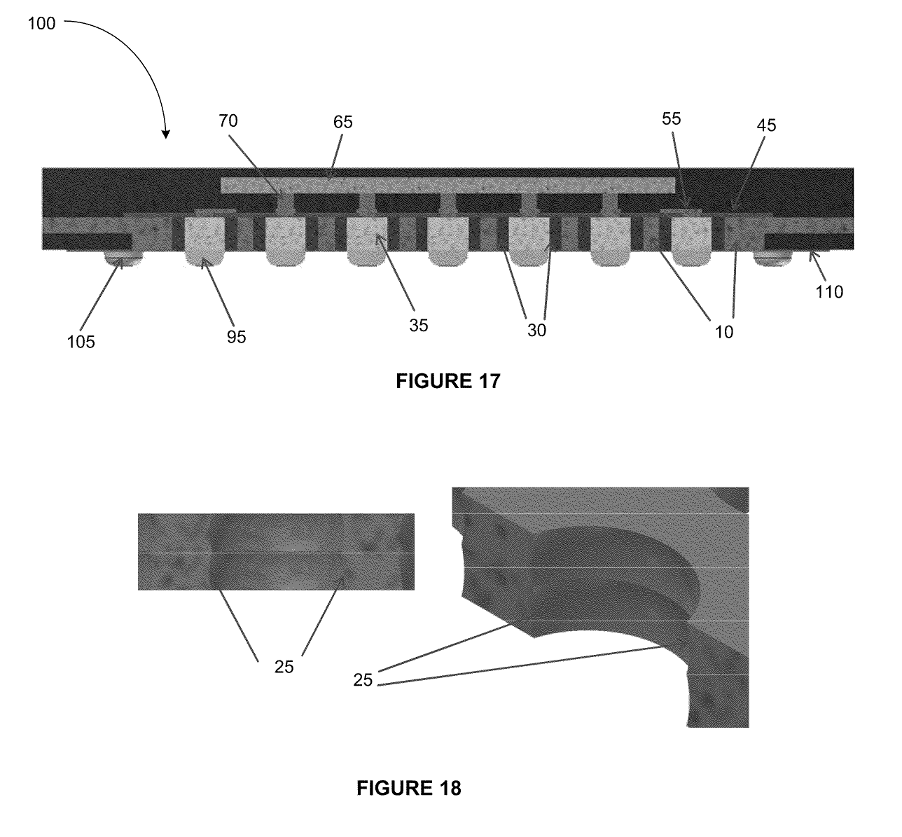

A side view of the completed semiconductor package 100 is shown in FIG. 17. As seen in this Figure, the heatsink terminals 105 are located near the periphery of the package 100, and extend from the bottom surface of the package. The die 65 containing the IC devices is connected via bumps 70 and routing connections 55 to the leadframe 10. The solder mask 45 is located between the routing connections 55 and the leadframe 10. The leadframe 10 also contains the thermally-conductive isolation vias 30, with the via holes 35 located in the center therein, and with the bumps 95 extending outside the molding material 80. The material of the leadframe 10, being thermally conductive, operates as an embedded heatsink to help conduct heat away from the IC device in the die 65 and into the ambient atmosphere. In the depicted embodiments, a solder mask 110 has been provided between the leadframe 10 and the heatsink terminals 105.

FIG. 18 illustrates a close-up view of the locking feature 25. As can be seen in this Figure, the locking feature 25 comprises a substantially concave shape which allows the leadframe 10 to firmly hold the thermal conductive isolation vias during any reflow process. While the shape illustrated in FIG. 18 is substantially circular, other shapes can be used as the locking feature, including rectangular (as shown in FIG. 1) or square shapes.

In some embodiments, the packages can be configured to contain more than a single die. In these embodiments, the leadframe 10 could be made larger, a second set of leadframe holes 20 and via holes 35 formed and filled in, and a second set of routing connectors could be supplied around the periphery of the larger leadframe. A second die could be attached to the die 65 (the first die). The backside of the second die could be attached to the backside of the first die, thereby leaving the front side of the second die exposed. The second die could comprise contact pads which are available for electrical connection to the second set of routing connections. Typically, those contact pads are located in the periphery of the second die. Those contact pads can then be electrically connected to one or more of the shorter leads in any known manner, including using any wire bonding process.

The semiconductor packages described above have several features. First, relative to flip-chip quad flat non-leaded package, flip chip thermally-enhanced BGA packages, and enhanced BGA-grounded heatsink packages which have a thickness of about 0.8 mm to about 1 mm, the packages described herein are thinner and have a thickness ranging from about 0. 5mm to about 0.8 mm since they do not require an additional heatsink that is mounted to the package. At the same time, relative to these devices, the packages described herein have a full land array, which gives a smaller footprint and a higher I/O capacity to these mentioned packages. Second, the packages described herein have a better thermal dissipation for multilevel packages or 2-layer BGA packages because of the embedded heatsink while at the same time, the package is kept thin and small, making the packages especially useful for portable electronic devices. Thus, the packages described herein comprise a small, thin, high I/O package with a better thermal dissipation, yielding better product performance.

In some embodiments, the application relates to a method for making a semiconductor package by providing a die containing an integrated circuit device, providing a leadframe containing an array of holes with a layout corresponding to the land pad array of the package, wherein the holes contain a thermally-conductive dielectric material with a via therein containing an electrically conductive material, providing a land pad array on the array of holes, and providing a molding material encapsulating the die and the leadframe except for the land pad array.

In other embodiments, the application relates to a method for making semiconductor package by forming a leadframe with an array of holes, depositing a thermally-conductive insulating material in the array of holes, forming vias in the insulating material, depositing a conductive layer in the vias to form a land pad array, forming routing connectors extending away from the conductive layer, connecting a die containing an IC device on the routing connectors, and encapsulating a molding material around the die and the leadframe except for the land pad array.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor package, comprising:
a die containing an integrated circuit device;
a leadframe containing an array of holes, wherein the holes contain a thermally-conductive dielectric material in an outer portion and an electrically-conductive material in an inner portion of the holes;
routing connectors connecting the integrated circuit device and the electrically conductive material in the holes; and
a molding material encapsulating the die and a portion of the leadframe.

2. The semiconductor package of claim 1, wherein the array of holes has a layout corresponding to the array of land pads for the package.

3. The semiconductor package of claim 2, wherein the land pads comprise a bump extending from the electrically conductive material.

4. The semiconductor package of claim 2, wherein the land pad array is formed in an inner portion on the bottom surface of the package and heat sink terminals are formed in an outer portion of the bottom surface of the package.

5. The semiconductor package of claim 1, further comprising a solder mask between the leadframe and the die, the solder mask containing openings where the routing connectors are located.

6. The semiconductor package of claim 1, wherein the thermally-conductive dielectric material comprises polymer-filled epoxy materials, ceramic-filled epoxy materials, or combinations thereof.

7. The semiconductor package of claim 1, further comprising stud bumps formed between the integrated circuit device and the routing connectors.

8. The semiconductor package of claim 1, wherein the leadframe contains a locking feature on an external edge.

9. The semiconductor package of claim 2, wherein the molding material does not encapsulate the land pad array.

10. The semiconductor package of claim 1, wherein the leadframe operates as an embedded heat sink to conduct heat away from the integrated circuit device.

11. An electronic apparatus containing a semiconductor package, the package comprising:
a die containing an integrated circuit device;
a leadframe containing an array of holes, wherein the holes contain a thermally-conductive dielectric material in an outer portion and an electrically-conductive material in an inner portion of the holes;
routing connectors connecting the integrated circuit device and the electrically conductive material in the holes; and
a molding material encapsulating the die and a portion of the leadframe.

12. The apparatus of claim 11, wherein the array of holes has a layout corresponding to the array of land pads for the package.

13. The apparatus of claim 12, wherein the land pads comprise a bump extending from the electrically conductive material.

14. The apparatus of claim 12, wherein the land pad array is formed in an inner portion on the bottom surface of the package and heat sink terminals are formed in an outer portion of the bottom surface of the package.

15. The apparatus of claim 12, further comprising a solder mask between the leadframe and the die, the solder mask containing openings where the routing connectors are located.

16. The apparatus of claim 11, wherein the thermally-conductive dielectric material comprises polymer-filled epoxy materials, ceramic-filled epoxy materials, or combinations thereof.

17. The apparatus of claim 11, further comprising stud bumps formed between the integrated circuit device and the routing connectors.

18. The apparatus of claim 11, wherein the leadframe contains a locking feature on an external edge.

19. The apparatus of claim 12, wherein the molding material does not encapsulate the land pad array.

20. The apparatus of claim 11, wherein the leadframe operates as an embedded heat sink to conduct heat away from the integrated circuit device.

21. A leadframe for a semiconductor package, the leadframe operating as an embedded heatsink and comprising:
an array of holes, wherein the holes contain a thermally-conductive dielectric material selected from polymer-filled epoxy materials, ceramic-filled epoxy materials, or combinations thereof in an outer portion of the holes and an electrically-conductive material in an inner portion of the holes; and
a locking feature on an external edge.
